(19) United States
(12) Patent Application Publication
(10) Pub. No.: US 2026/0152386 A1
(43) Pub. Date: Jun. 4, 2026

(54) MICROELECTROMECHANICAL DEVICE

(71) Applicant: ZILLTEK TECHNOLOGY CORP., Hsinchu City (TW)

(72) Inventors: JEN-YI CHEN, Hsinchu City (TW); CHIH-CHANG HOU, Hsinchu City (TW); KAI-YU JIANG, Hsinchu City (TW)

(21) Appl. No.: 18/965,016

(22) Filed: Dec. 2, 2024

(51) Int. Cl. B81B 7/00; G01K 7/22; H01C 7/00

(52) U.S. Cl. CPC B81B 7/0087; G01K 7/226; B81B 2201/0271; B81B 2203/0154; B81B 2203/0307; H01C 7/008

(57) ABSTRACT

A microelectromechanical device includes a substrate, a dielectric layer, two conductive anchor components, a microelectromechanical structure, and at least one elastic thermistor. The dielectric layer is disposed on the substrate. The two conductive anchor components are disposed on the dielectric layer, and are spaced apart from each other along an extension direction of the substrate. One of two ends of the elastic thermistor is connected to one of the two conductive anchor components, and another one of the two ends of the elastic thermistor is connected to one of two ends of the microelectromechanical structure. Another one of the two ends of the microelectromechanical structure is connected to another one of the two conductive anchor components. The microelectromechanical structure and the substrate are spaced apart from each other by the elastic thermistor, so as to form a first predetermined gap along a height direction of the substrate.

### FIELD OF THE DISCLOSURE

The present disclosure relates to a device, and more particularly to a microelectromechanical device.

### BACKGROUND OF THE DISCLOSURE

Conventional microelectromechanical devices are highly sensitive to temperature during operation. Specifically, when an ambient temperature of the conventional microelectromechanical device changes, the conventional microelectromechanical device is likely to have an unstable operation, thereby resulting in poor performance or inaccuracy. Therefore, the conventional microelectromechanical device is further equipped with a temperature sensor to detect the ambient temperature, so that the conventional microelectromechanical device can make a compensation based on the ambient temperature. However, the temperature sensor used in the conventional microelectromechanical device measures the ambient temperature rather than an actual temperature inside the conventional microelectromechanical device. As such, accuracy of a compensation behavior still has room for improvement.

In addition, when the conventional microelectromechanical device is in operation, energy of the conventional microelectromechanical device tends to dissipate through anchor points, which may lead to energy loss.

### SUMMARY OF THE DISCLOSURE

In response to the above-referenced technical inadequacies, the present disclosure provides a microelectromechanical device.

In order to solve the above-mentioned problems, one of the technical aspects adopted by the present disclosure is to provide a microelectromechanical device. The microelectromechanical device includes a substrate, a dielectric layer, two conductive anchor components, a microelectromechanical structure, and at least one elastic thermistor. The substrate has a height direction and an extension direction that is perpendicular to the height direction. The dielectric layer is disposed on the substrate. The two conductive anchor components are disposed on the substrate through the dielectric layer, and the two conductive anchor components are spaced apart from each other along the extension direction. The at least one elastic thermistor includes a fixed portion, and an elastic portion connected to the fixed portion, the fixed portion is connected to one of the two conductive anchor components, the elastic portion is connected to one of two ends of the microelectromechanical structure, and another one of the two ends of the microelectromechanical structure is directly or indirectly connected to another one of the two conductive anchor components. The microelectromechanical structure and the substrate are spaced apart from each other by the at least one elastic thermistor, so as to form a first predetermined gap along the height direction.

Therefore, in the microelectromechanical device provided by the present disclosure, by virtue of “the fixed portion being connected to one of the two conductive anchor components, the elastic portion being connected to one of two ends of the microelectromechanical structure, and another one of the two ends of the microelectromechanical structure being directly or indirectly connected to another one of the two conductive anchor components,” and “the microelectromechanical structure and the substrate being spaced apart from each other by the at least one elastic thermistor, so as to form a first predetermined gap along the height direction,” the microelectromechanical device can accurately measure a temperature thereof and reduce energy dissipation from anchor points (e.g., the two conductive anchor components).

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic partial planar view of a microelectromechanical device according to the present disclosure;

FIG. 2 is a schematic enlarged view of part II of FIG. 1;

FIG. 3 is a schematic cross-sectional view taken along line III-III of FIG. 1;

FIG. 4 is a schematic cross-sectional view of the microelectromechanical device according to one embodiment of the present disclosure;

FIG. 5 is a schematic partial planar view of the microelectromechanical device according to another embodiment of the present disclosure;

FIG. 6 is a schematic partial planar view of the microelectromechanical device according to yet another embodiment of the present disclosure;

FIG. 7 is a schematic partial planar view of the microelectromechanical device according to still another embodiment of the present disclosure;

FIG. 8 is a schematic partial planar view of an elastic thermistor according to one embodiment of the present disclosure;

FIG. 9 is a schematic partial planar view of the microelectromechanical device according to still yet another embodiment of the present disclosure; and

FIG. 10 is a schematic partial planar view of the microelectromechanical device according to still yet another embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

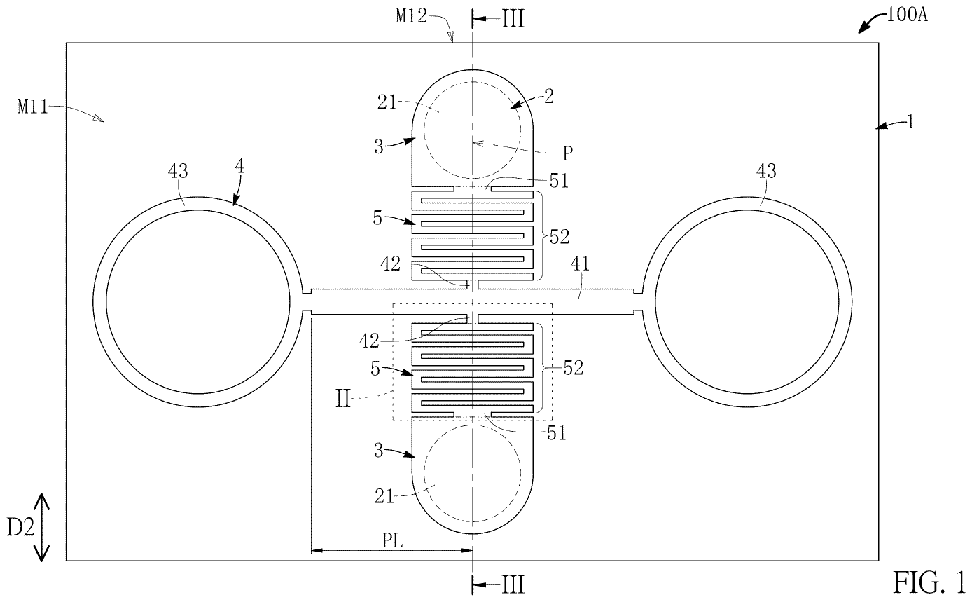

Referring to FIG. 1 to FIG. 7, an embodiment of the present disclosure provides a microelectromechanical device. As shown in FIG. 1 to FIG. 3, an microelectromechanical device 100A includes a substrate 1, a dielectric layer 2 disposed on the substrate 1, two conductive anchor components 3 disposed on the dielectric layer 2, and a microelectromechanical structure 4 and at least one elastic thermistor 5 that are located between the two conductive anchor components 3. The following description describes the structure and connection relation of each component of the microelectromechanical device 100A.

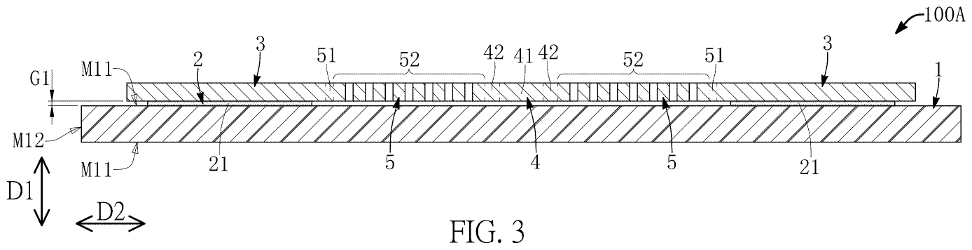

Referring to FIG. 1 and FIG. 3, for convenience of description, the substrate 1 defines a height direction D1 and an extension direction D2 that is perpendicular to the height direction D1. In the present embodiment, the substrate 1 is a plate-like structure, and has two wide side surfaces M11 and a peripheral side surface M12 that is connected to the two wide side surfaces M11. A direction along which any one of the two wide side surfaces M11 faces toward another one of the two wide side surfaces M11 is the height direction D1, and a lengthwise extension of any one of the wide side surfaces M11 is the extension direction D2.

Moreover, the dielectric layer 2 is disposed on one of the wide side surfaces M11 of the substrate 1. In practice, the dielectric layer 2 can be an oxide layer deposited on the substrate 1, but the present disclosure is not limited thereto. In addition, the dielectric layer 2 in the present embodiment has two insulating portions 21 spaced apart from each other along the extension direction D2.

Referring to FIG. 1 to FIG. 3, the two conductive anchor components 3 are respectively disposed on the two insulating portions 21 of the dielectric layer 2, and the two conductive anchor components 3 can be disposed on the substrate 1 through the two insulating portions 21. In addition, the two conductive anchor components 3 are spaced apart from each other along the extension direction D2.

Referring to FIG. 1 to FIG. 3, the microelectromechanical structure 4 and the at least one elastic thermistor 5 are arranged between the two conductive anchor components 3. The at least one elastic thermistor 5 can be connected to the microelectromechanical structure 4 and one of the two conductive anchor components 3. In this way, the microelectromechanical structure 4 is suspended relative to the substrate 1, and a temperature of the microelectromechanical structure 4 can be sensed by the at least one elastic thermistor 5 in a direct conductive manner.

Specifically, the at least one elastic thermistor 5 includes a fixed portion 51 and an elastic portion 52 connected to the fixed portion 51. The fixed portion 51 is connected to one of the two conductive anchor components 3, the elastic portion 52 is connected to one of two ends of the microelectromechanical structure 4, and another one of the two ends of the microelectromechanical structure 4 is directly or indirectly connected to another one of the two conductive anchor components 3. Accordingly, the microelectromechanical structure 4 and the substrate 1 are spaced apart from each other by the at least one elastic thermistor 5, so as to form a first predetermined gap G1 along the height direction D1.

It should be noted that, since the microelectromechanical structure 4 does not contact the substrate 1 (i.e., the microelectromechanical structure 4 is in a suspended state relative to the substrate 1), the microelectromechanical structure 4 can utilize the elastic portion 52 to stretch or compress along the extension direction D2, so as to reduce energy dissipation through anchor points.

In practice, the microelectromechanical structure 4 can also utilize the elastic portion 52 to generate tensile or compressive deformation along the height direction D1, so as to move within the first predetermined gap G1. The predetermined gap G1 needs to have a sufficient distance, so that the microelectromechanical structure 4 is prevented from colliding with the substrate 1. Preferably, the first predetermined gap G1 is greater than or equal to 1 micrometer to ensure that the microelectromechanical structure 4 has a sufficient buffer space.

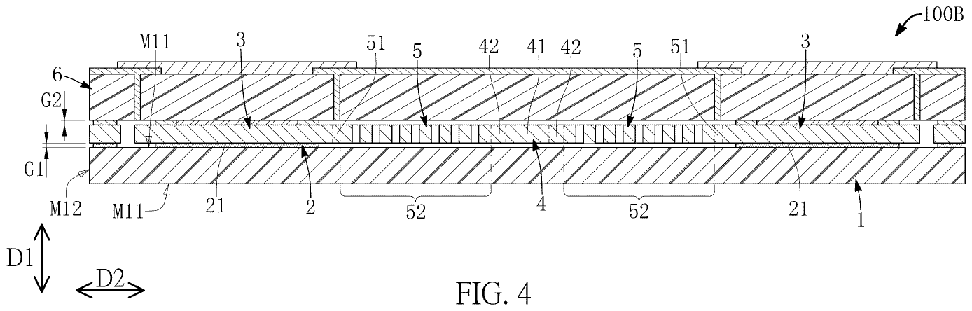

Naturally, when the microelectromechanical structure 4 and the at least one elastic thermistor 5 of the microelectromechanical device 100A are designed to be covered and sealed by a cover plate, a second predetermined gap G2 can be formed between the microelectromechanical structure 4 and the cover plate along the height direction D1, so as to prevent the microelectromechanical structure 4 from colliding with the cover plate. Specifically, as shown in FIG. 4, a microelectromechanical device 100B further includes a cover layer 6 (e.g., polysilicon), and the two conductive anchor components 3, the microelectromechanical structure 4, and the at least one elastic thermistor 5 are covered (and sealed) by the cover layer 6. The second predetermined gap G2 is between the cover layer 6 and the microelectromechanical structure 4, and the second predetermined gap G2 is preferably greater than or equal to 1 micrometer.

Moreover, the elastic portion 52 of the at least one elastic thermistor 5 in practice is a meander conductor having elastic tolerance. In other words, the meander conductor has a plurality of short segments A1 and a plurality of long segments A2 that are not parallel to the short segments A1, and a length LA2 of each of the long segments A2 is greater than a length LA1 of each of the short segments A1. The long segments A2 are arranged to be parallel to and spaced apart from each other, and the short segments A1 are connected to two ends of the long segments A2 in an alternating manner, so that the elastic portion 52 is formed by the short segments A1 and the long segments A2.

In order to facilitate understanding of how “the short segments A1 are connected to the long segments A2 in the alternating manner,” the following example is provided.

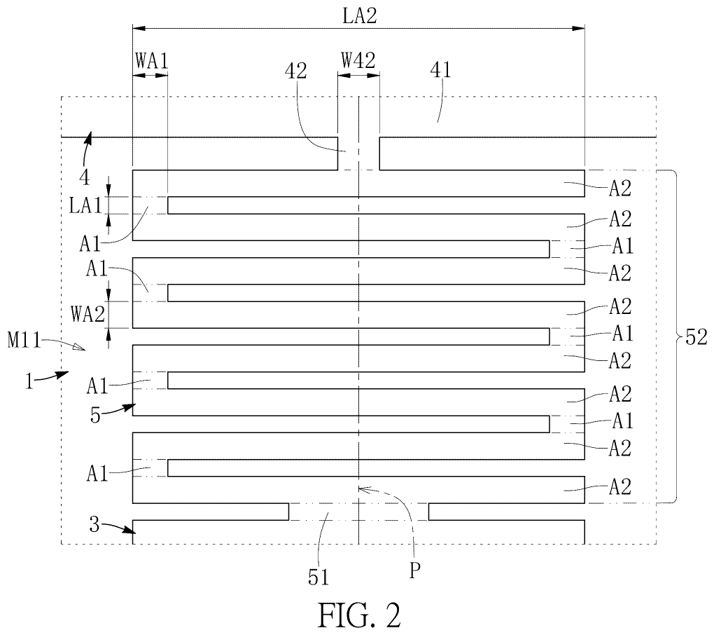

The long segments A2 have a first common side (e.g., a left side of the elastic portion 52 in FIG. 2) and a second common side (e.g., a right side of the elastic portion 52 in FIG. 2) that is opposite to the first common side. The long segments A2 are defined as a first long segment, a second long segment, . . . , and an Nth long segment. Similarly, the short segments A1 are defined as a first short segment, a second short segment, . . . , and an (N−1)th short segment. One end of the first long segment located at the first common side and one end of the second long segment located at the first common side are connected to the first short segment. One end of the second long segment located at the second common side and one end of the third long segment located at the second common side are connected to the second short segment. One end of the third long segment located on the first common side and one end of the fourth long segment located on the first common side are connected to the third short segment, and so on.

Accordingly, the at least one elastic thermistor 5 can have the fixed portion 51 for being fixed to the conductive anchor component 3 and the elastic portion 52 that can be stretched or compressed, so that the temperature of the microelectromechanical structure 4 can be directly measured (in a conductive manner) through the at least one elastic thermistor 5, and energy loss can be avoided through the elastic portion 52.

In other words, any elastic thermistor that does not simultaneously provide both “direct measurement of the temperature of the microelectromechanical structure 4” and “shock absorption effect for the microelectromechanical structure 4” is not the elastic thermistor 5 of the present disclosure. Moreover, the elastic thermistor 5 of the present disclosure detects temperature through the characteristic in which resistance varies with temperature. Since such a measurement method is known to those skilled in the art and is not the focus of the present disclosure, details thereof will not be described herein.

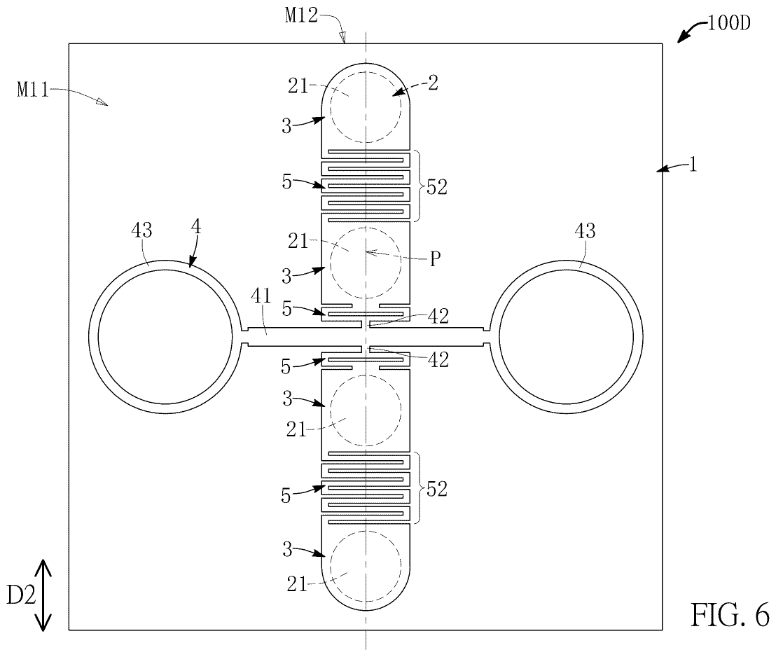

In practice, the at least one elastic thermistor 5 can also have an elastic portion without a meander conductor. For example, in a microelectromechanical device 100D shown in FIG. 6, the elastic thermistor 5 that is located adjacent to the microelectromechanical structure 4 utilizes a closed and elastic conductor as the elastic portion thereof.

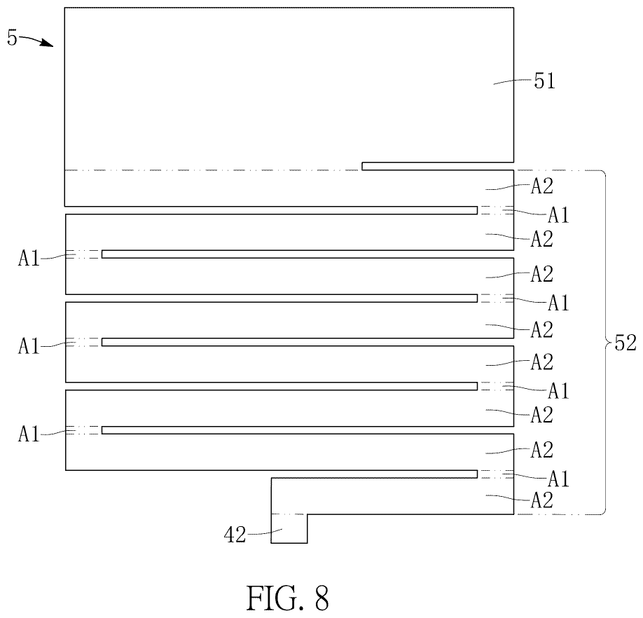

In addition, as shown in FIG. 8, a connection position between the fixed portion 51 and the elastic portion 52 can be designed to deviate from a center of the elastic thermistor 5 according to practical requirements.

It is worth mentioning that, in order to ensure that the at least one elastic thermistor 5 has an ideal shock absorption effect, a width of the meander conductor (i.e., a width WA1 of each of the short segments A1 and a width WA2 of each of the long segments A2) is preferably greater than or equal to 2 micrometers, a total length of the meander conductor (i.e., a sum of the lengths LA1 of the short segments A1 and the lengths LA2 of the long segments A2) is greater than or equal to 400 micrometers, and the length LA2 of each of the long segments A2 is within a range from 10 micrometers to 150 micrometers. However, the present disclosure is not limited thereto.

In one of the embodiments, a quantity of the at least one elastic thermistor 5 may be two, the elastic portions 52 of the two elastic thermistors 5 are respectively connected to the two ends of the microelectromechanical structure 4, and the fixed portions 51 of the two elastic thermistors 5 are respectively connected to the two conductive anchor components 3 (e.g., the microelectromechanical device 100A shown in FIG. 1).

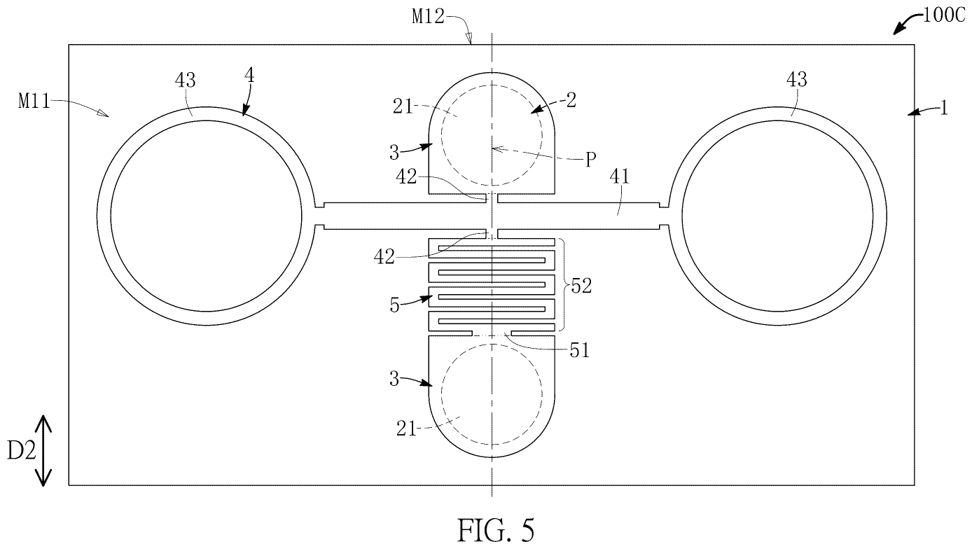

In another one of embodiments, the quantity of the at least one elastic thermistor 5 may be one, one of the two ends of the microelectromechanical structure 4 is connected to one of the two conductive anchor components 3 through the elastic thermistor 5, and another one of the two ends of the microelectromechanical structure 4 is fixed to another one of the two conductive anchor components 3 (e.g., a microelectromechanical device 100C shown in FIG. 5).

Referring to FIG. 1 to FIG. 3, in the present embodiment, the material of the microelectromechanical structure 4 is identical to that of the at least one elastic thermistor 5, and the microelectromechanical structure 4 is directly connected to the at least one elastic thermistor 5, so as to ensure that the temperature of the microelectromechanical structure 4 can be transmitted to the at least one elastic thermistor 5 in real time. It should be noted that a resistivity of the microelectromechanical structure 4 is preferably different from a resistivity of the at least one elastic thermistor 5, and a resistance value of the at least one elastic thermistor 5 is greater than or equal to 100 ohms.

The microelectromechanical structure 4 can be exemplified to be a resonator, and includes a coupling beam 41, two connection structures 42 located at a center of the coupling beam 41, and two coupling loops 43 that are connected to the coupling beam 41. The two connection structures 42 can be connected to the elastic portions 52 of the two elastic thermistors 5 (as shown in FIG. 1), or the two connection structures 42 can be respectively connected to the elastic portions 52 of the elastic thermistor 5 and the two conductive anchor components 3 (as shown in FIG. 5).

In order for the microelectromechanical structure 4 to effectively reduce energy loss, center points of the two connection structures 42 and center points of the long segments A2 are preferably passed through by a centerline P of the microelectromechanical device 100 along the extension direction D2, but the present disclosure is not limited thereto.

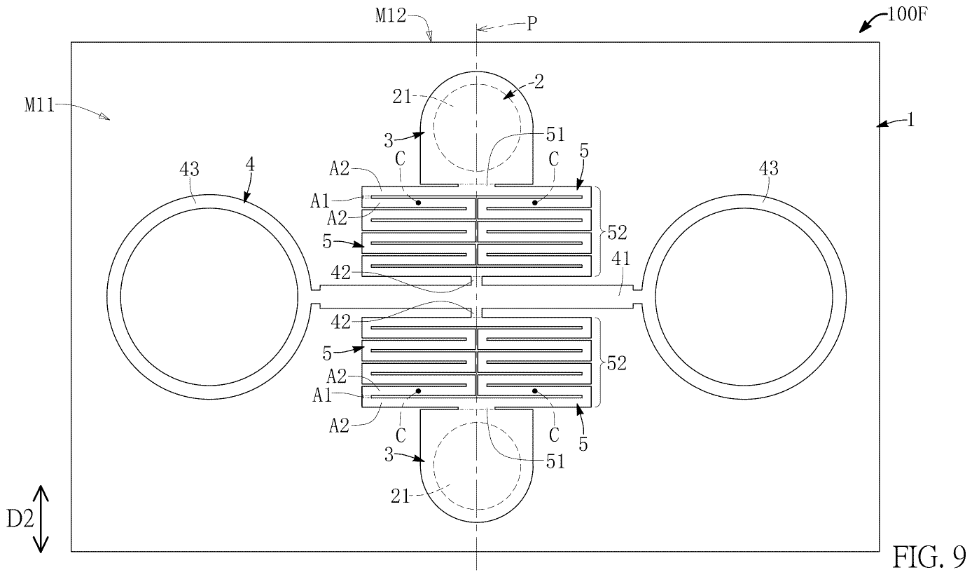

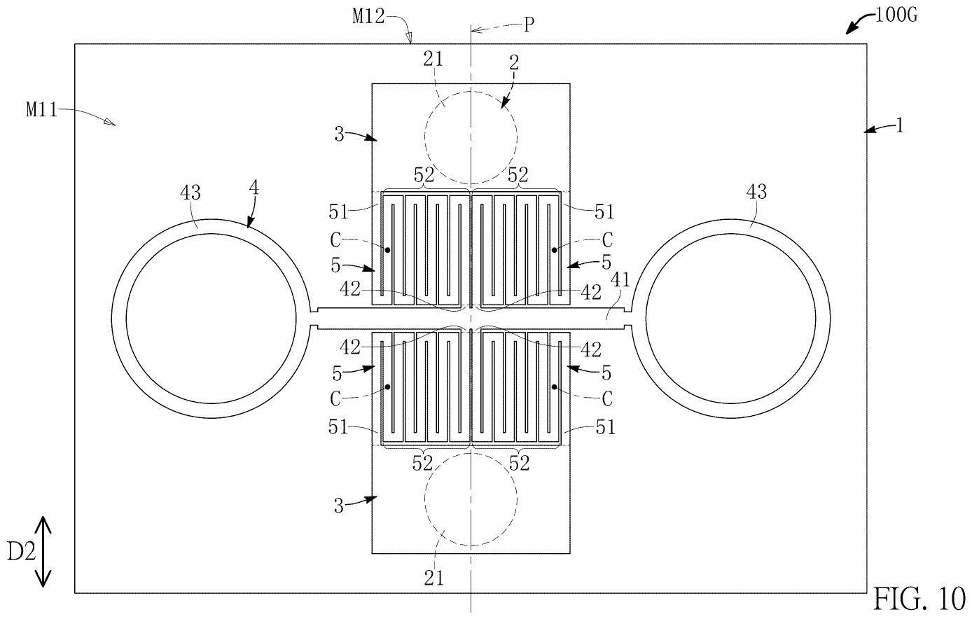

For example, as shown in FIG. 9 and FIG. 10, the center points of the two connection structures 42 are passed through by the centerline P, and center points C of the long segments A2 are located on two sides of the centerline P. That is to say, the center points of the long segments A2 are not passed through by the centerline P. In addition, for the shock absorption effect of connecting the microelectromechanical structure 4 to the at least one elastic thermistor 5 (and the conductive anchor component 3), a predetermined length PL from any one of the two connection structures 42 to any one of the two coupling loops 43 along the coupling beam 41 is ¼ of a wavelength corresponding to an operating frequency that is suitable for the microelectromechanical device, and a width W42 of each of the two connection structures 42 is less than 15% of the predetermined length PL.

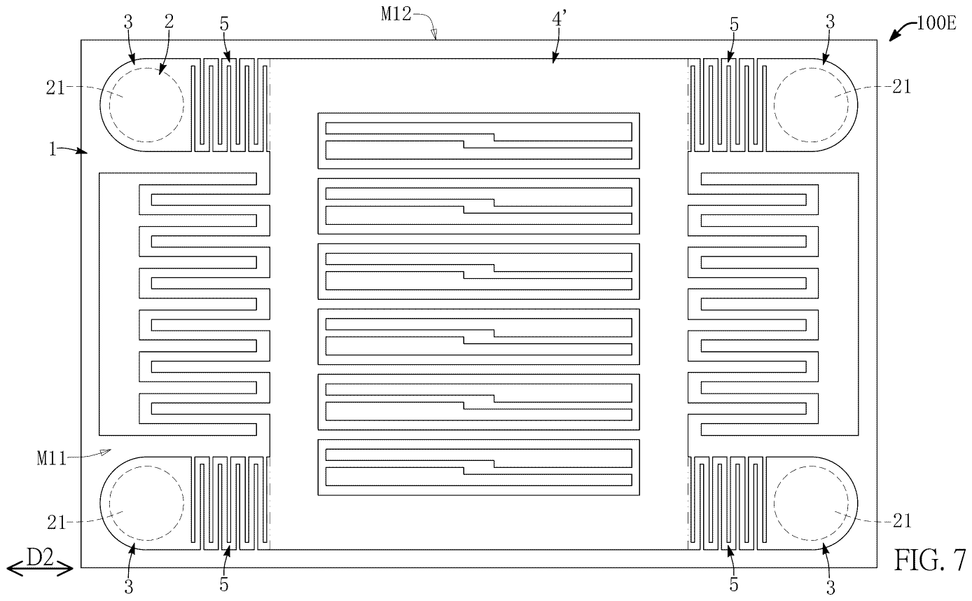

It should be noted that the microelectromechanical structure 4 of the present disclosure is not limited to being the resonator. For example, as shown in FIG. 7, a microelectromechanical device 100E may feature a microelectromechanical structure 4′ that is exemplified to be a gyroscope, and a quantity of the conductive anchor component 3 and the quantity of the elastic thermistor 5 can be four.

Naturally, although the microelectromechanical structure 4 is the resonator, the quantities of the conductive anchor component 3 and the elastic thermistor 5 can also be adjusted as appropriate (e.g., the microelectromechanical device 100D shown in FIG. 6).

### Beneficial Effects of the Embodiments

In conclusion, in the microelectromechanical device provided by the present disclosure, by virtue of “the fixed portion being connected to one of the two conductive anchor components, the elastic portion being connected to one of two ends of the microelectromechanical structure, and another one of the two ends of the microelectromechanical structure being directly or indirectly connected to another one of the two conductive anchor components,” and “the microelectromechanical structure and the substrate being spaced apart from each other by the at least one elastic thermistor, so as to form a first predetermined gap along the height direction,” the microelectromechanical device can accurately measure a temperature thereof and reduce energy dissipation from anchor points (e.g., the two conductive anchor components).

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A microelectromechanical device, comprising:
a substrate having a height direction and an extension direction that is perpendicular to the height direction;
a dielectric layer disposed on the substrate;
two conductive anchor components disposed on the substrate through the dielectric layer, wherein the two conductive anchor components are spaced apart from each other along the extension direction; and
a microelectromechanical structure and at least one elastic thermistor, wherein the at least one elastic thermistor includes a fixed portion and an elastic portion connected to the fixed portion, the fixed portion is connected to one of the two conductive anchor components, the elastic portion is connected to one of two ends of the microelectromechanical structure, and another one of the two ends of the microelectromechanical structure is directly or indirectly connected to another one of the two conductive anchor components, and wherein the microelectromechanical structure and the substrate are spaced apart from each other by the at least one elastic thermistor, so as to form a first predetermined gap along the height direction.

2. The microelectromechanical device according to claim 1, wherein a quantity of the at least one elastic thermistor is two, the elastic portions of the two elastic thermistors are respectively connected to the two ends of the microelectromechanical structure, and the fixed portions of the two elastic thermistors are respectively connected to the two conductive anchor components.

3. The microelectromechanical device according to claim 1, wherein the elastic portion is a meander conductor having elastic tolerance, and a width of the meander conductor is greater than or equal to 2 micrometers.

4. The microelectromechanical device according to claim 1, wherein the elastic portion is a meander conductor having elastic tolerance, and a total length of the meander conductor is greater than or equal to 400 micrometers.

5. The microelectromechanical device according to claim 1, wherein the elastic portion is a meander conductor having elastic tolerance, and the meander conductor has a plurality of short segments and a plurality of long segments that are not parallel to the short segments; wherein a length of each of the long segments is greater than a length of each of the short segments, the fixed portion is formed by one of the short segments, and the elastic portion is formed by remaining ones of the short segments and the long segments; wherein the length of each of the long segments is within a range from 10 micrometers to 150 micrometers.

6. The microelectromechanical device according to claim 1, wherein the microelectromechanical device is suitable for an operating frequency; wherein the microelectromechanical structure includes a coupling beam, two connection structures located at a center of the coupling beam, and two coupling loops that are connected to the coupling beam; wherein a predetermined length from any one of the two connection structures to any one of the two coupling loops along the coupling beam is ¼ of a wavelength corresponding to the operating frequency, and a width of each of the two connection structures is less than 15% of the predetermined length.

7. The microelectromechanical device according to claim 1, wherein the first predetermined gap is greater than or equal to 1 micrometer.

8. The microelectromechanical device according to claim 1, wherein a quantity of the at least one elastic thermistor is one, one of two ends of the microelectromechanical structure is connected to one of the two conductive anchor components through the elastic thermistor, and another one of the two ends of the microelectromechanical structure is fixed to another one of the two conductive anchor components.

9. The microelectromechanical device according to claim 1, further comprising a cover layer, wherein the two conductive anchor components, the microelectromechanical structure, and the at least one elastic thermistor are covered by the cover layer; wherein a second predetermined gap is formed between the cover layer and the microelectromechanical structure along the height direction, and the second predetermined gap is greater than or equal to 1 micrometer.

10. The microelectromechanical device according to claim 1, wherein the microelectromechanical device has a centerline along the extension direction; wherein the elastic portion is a meander conductor having elastic tolerance, and the meander conductor has a plurality of short segments and a plurality of long segments that are not parallel to the short segments; wherein a length of each of the long segments is greater than a length of each of the short segments, the fixed portion is formed by one of the short segments, and the elastic portion is formed by remaining ones of the short segments and the long segments; wherein the microelectromechanical structure includes a coupling beam, two connection structures located at a center of the coupling beam, and two coupling loops that are connected to the coupling beam; wherein center points of the long segments and center points of the two connection structures are passed through by the centerline.

11. The microelectromechanical device according to claim 1, wherein the microelectromechanical device has a centerline along the extension direction; wherein the elastic portion is a meander conductor having elastic tolerance, and the meander conductor has a plurality of short segments and a plurality of long segments that are not parallel to the short segments; wherein a length of each of the long segments is greater than a length of each of the short segments, the fixed portion is formed by one of the short segments, and the elastic portion is formed by remaining ones of the short segments and the long segments; wherein the microelectromechanical structure includes a coupling beam, two connection structures located at a center of the coupling beam, and two coupling loops that are connected to the coupling beam; wherein center points of the two connection structures are passed through by the centerline, and center points of the long segments are located on two sides of the centerline.

12. The microelectromechanical device according to claim 1, wherein a resistivity of the microelectromechanical structure is different from a resistivity of the at least one elastic thermistor.

13. The microelectromechanical device according to claim 12, wherein a resistance value of the at least one elastic thermistor is greater than or equal to 100 ohms.
